(19) United States
(12) Patent Application Publication
(10) Pub. No.: US 2023/0331101 A1
(43) Pub. Date: Oct. 19, 2023

(54) CONTACTLESS CHARGER

(71) Applicant: SUBARU CORPORATION, Tokyo (JP)

(72) Inventor: Kenta WAKABAYASHI, Tokyo (JP)

(21) Appl. No.: 18/124,358

(22) Filed: Mar. 21, 2023

(30) Foreign Application Priority Data
Apr. 15, 2022 (JP) 2022-067772

(51) Int. Cl. B60L 53/12; H01M 10/63; H01M 10/615; H01M 10/613; G01R 31/382; B60K 1/04

(52) U.S. Cl. CPC B60L 53/12; H01M 10/63; H01M 10/615; H01M 10/613; G01R 31/382; B60K 1/04

(57) ABSTRACT

A contactless charger includes a vehicle-mounted power receiving coil contactlessly receiving power from a power supply coil and supplying the power to a battery, a vehicle-mounted shutter positioned between the two coils, and switching valves. The shutter includes an inner flow path through which a heat medium flows, and a movable member opened and closed to change its projected area with respect to the power receiving coil, generating heat due to electromagnetic induction induced with the power supply coil, and transferring the heat to the heat medium flowing through the inner flow path. The switching valves turn on or off coupling between the inner flow path and each of a battery temperature control circuit in which the heat medium for adjusting a temperature of the battery circulates and a cabin air-conditioning circuit in which the heat medium contributing to air conditioning in a vehicle cabin circulates.

### CROSS-REFERENCE TO RELATED APPLICATIONS

The present application claims priority from Japanese Patent Application No. 2022-067772 filed on Apr. 15, 2022, the entire contents of which are hereby incorporated by reference.

### BACKGROUND

The disclosure relates to a contactless charger.

For example, Japanese Unexamined Patent Application Publication No. 2018-129205 discloses a technique of charging a battery mounted in a vehicle contactlessly from the outside of the vehicle. In the disclosed contactless charging, a power supply coil is disposed in the ground, and a power receiving coil is disposed in the vehicle. Power is contactlessly supplied to the power receiving coil from the power supply coil via an electromagnetic field. The battery is charged with the power supplied to the power receiving coil.

### SUMMARY

An aspect of the disclosure provides a contactless charger. The contactless charger includes a power receiving coil, a shutter, and switching valves. The power receiving coil is mounted in a vehicle and configured to contactlessly receive power from a power supply coil outside the vehicle via an electromagnetic field and to supply the received power to a batter. The shutter is disposed in the vehicle to be positioned between the power receiving coil and the power supply coil when the power receiving coil is positioned to face the power supply coil. The shutter includes an inner flow path through which a heat medium flows, and a movable member. The movable member is configured to open and close so as to change a projected area of the movable member with respect to the power receiving coil, to generate heat due to electromagnetic induction induced with the power supply coil, and to transfer the generated heat to the heat medium flowing through the inner flow path. The switching valves are configured to turn on or off coupling between the inner flow path and a battery temperature control circuit in which the heat medium for adjusting a temperature of the battery circulates, and to turn on or off coupling between the inner flow path and a cabin air-conditioning circuit in which the heat medium contributing to air conditioning in a cabin of the vehicle circulates.

### BRIEF DESCRIPTION OF THE DRAWINGS

The accompanying drawings are included to provide a further understanding of the disclosure and are incorporated in and constitute a part of this specification. The drawings illustrate an embodiment and, together with the specification, serve to describe the principles of the disclosure.

FIG. 1 is a schematic view of a contactless charging system according to an embodiment;

FIG. 2 is a block diagram illustrating a configuration of a vehicle to which a contactless charger is applied;

FIG. 3 is a plan view of a shutter;

FIG. 4 is a side view of the shutter;

FIG. 5 is an explanatory view illustrating an action of the shutter;

FIG. 6 is an explanatory view illustrating an action of the shutter;

FIG. 7 is an explanatory view illustrating an action of the shutter;

FIG. 8 illustrates an example of a method of determining an angle of the movable member;

FIG. 9 is a schematic view illustrating coupling relationships among an inner flow path, a battery temperature control circuit, and a cabin air-conditioning circuit;

FIG. 10 illustrates an example of heat medium flow paths;

FIG. 11 illustrates an example of the heat medium flow paths;

FIG. 12 illustrates an example of the heat medium flow paths;

FIG. 13 illustrates an example of the heat medium flow paths;

FIG. 14 illustrates an example of the heat medium flow paths;

FIG. 15 illustrates power input/output characteristics of a battery;

FIG. 16 illustrates an example of a setting map; and

FIG. 17 is a flowchart illustrating an operation flow of a control device.

### DETAILED DESCRIPTION

A battery has such a characteristic that, when a temperature of the battery drops, allowable maximum input power, namely maximum power capable of being input to the battery, reduces. Accordingly, in spite of power being supplied from the power supply coil, the battery cannot be properly charged and the supplied power is wasted in the state in which the allowable maximum input power is lower than the supplied power.

It is desirable to provide a contactless charger capable of utilizing supplied power without a loss.

An embodiment of the disclosure will be described in detail below with reference to the accompanying drawings. Particular sizes, materials, numerical values, and so on indicated in the embodiment are merely examples for making the disclosure easier to understand and are not intended to limit the disclosure unless otherwise specified. In this Specification and the drawings, components having substantially the same functions or configurations are denoted by the same reference signs, and duplicate description of those components is omitted. Moreover, components not directly related to the disclosure are omitted from the drawings.

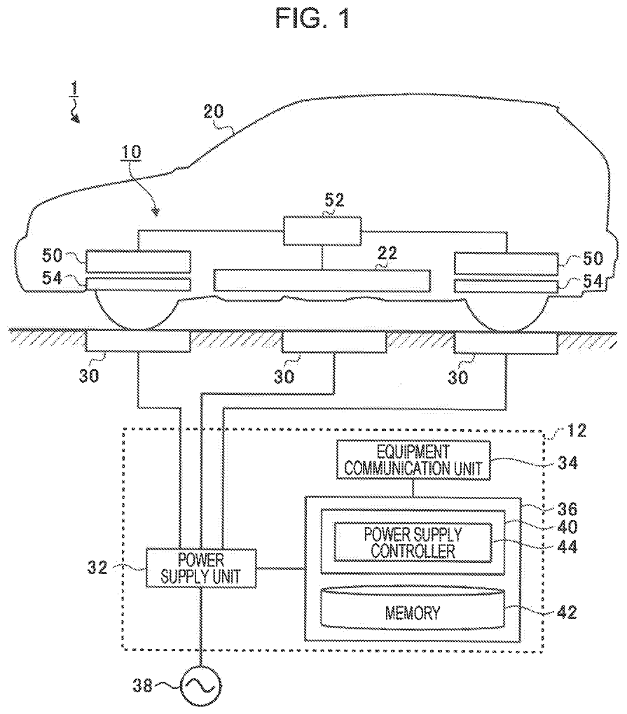

FIG. 1 is a schematic view of a contactless charging system 1 according to an embodiment. The contactless charging system 1 includes a contactless charger 10 and power supply equipment 12. The contactless charger 10 is mounted in a vehicle 20.

The vehicle 20 is, for example, an electric automobile or a hybrid electric automobile and includes a motor serving as a drive source for traveling. The vehicle 20 includes a battery 22. The battery 22 is, for example, a lithium ion battery and is a rechargeable secondary battery. The battery 22 supplies power to the motor serving as the drive source.

The power supply equipment 12 is disposed outside the vehicle 20. The power supply equipment 12 includes a power supply coil 30, a power supply unit 32, an equipment communication unit 34, and an equipment control device 36. The power supply coil 30 is installed in the ground of, for example, a traveling road or a parking lot. The power supply coil 30 may be buried in the ground. Instead, at least part of the power supply coil may be exposed to the ground surface. Multiple power supply coils 30 may be installed along the traveling road in, for example, vehicle stop positions at the intersection.

The power supply unit 32 is coupled to the power supply coil 30 and a power supply source 38. The power supply source 38 is, for example, a commercial power system. The power supply unit 32 converts commercial frequency power supplied from the power supply source 38 to high-frequency power and supplies the high-frequency power to the power supply coil 30. The power supply coil 30 delivers, to a space above the ground, an electromagnetic wave in accordance with the power supplied through the power supply unit 32. In other words, when the high-frequency power is supplied to the power supply coil 30, an electromagnetic field around the power supply coil 30 varies with time. Although described in detail later, when a power receiving coil 50 is present near the power supply coil 30, power is generated in the power receiving coil 50 in accordance with a time-dependent variation of the electromagnetic field around the power supply coil 30. Thus, the electromagnetic wave delivered from the power supply coil 30 is received by the power receiving coil 50, and the power is supplied from the power supply coil 30 to the power receiving coil 50. Hereinafter, the power supplied from the power supply unit 32 to the power supply coil 30, namely the power of the electromagnetic wave delivered to the space from the power supply coil 30, is called “supplied power” in some cases. The equipment communication unit 34 can communicate with the vehicle 20 around the power supply equipment 12.

The equipment control device 36 includes one or multiple processors 40 and one or multiple memories 42 coupled to the one or multiple processors 40. The one or multiple memories 42 include ROM in which programs and so on are stored, and RAM serving as a work area. The one or multiple processors 40 in the equipment control device 36 cooperate with the programs stored in the one or multiple memories 42 and control the entirety of the power supply equipment 12. The one or multiple processors 40 further serve as a power supply controller 44 by executing the programs.

The power supply controller 44 controls execution of the power supply performed through the power supply unit 32 and the power supply coil 30. For example, the power supply controller 44 transmits, to the vehicle 20 around the power supply equipment 12, information of the supplied power, namely the power capable of being supplied to the vehicle 20 from the power supply equipment 12, via the equipment communication unit 34. When an acknowledgement is received from the vehicle 20 around the power supply equipment 12, the power supply controller 44 controls the power supply unit 32 to deliver an electromagnetic wave from the power supply coil 30.

The contactless charger 10 mounted in the vehicle includes the power receiving coil 50, a converter 52, and a shutter 54.

The power receiving coil 50 is disposed in a bottom portion of the vehicle 20 at, for example, each of a position between left and right front wheels and a position between left and right rear wheels. While two power receiving coils 50 are disposed in the vehicle 20 in FIG. 1, at least one or more power receiving coils 50 may be disposed in the vehicle 20. The power receiving coils 50 are each disposed to face the ground, and when the vehicle 20 is positioned above the power supply coil 30, the power receiving coil 50 faces the power supply coil 30. The power receiving coil 50 can contactlessly receive the power from the power supply coil 30 via an electromagnetic field. Hereinafter, the power received by the power receiving coil 50 via the electromagnetic field is called “received power” in some cases.

The converter 52 is electrically coupled to the power receiving coil 50 and the battery 22. The converter 52 converts AC power received by the power receiving coil 50 to DC power and supplies the DC power to the battery 22. Thus, in the contactless charger 10, the battery 22 can be charged with the power received by the power receiving coil 50.

The shutter 54 is disposed on a side closer to a bottom surface of the vehicle 20 than the power receiving coil 50. The shutter 54 is disposed in the vehicle 20 to be positioned between the power receiving coil 50 and the power supply coil 30 when the power receiving coil 50 is positioned to face the power supply coil 30. The shutter 54 is arranged substantially parallel to the power receiving coil 50. Details of the shutter 54 will be described later.

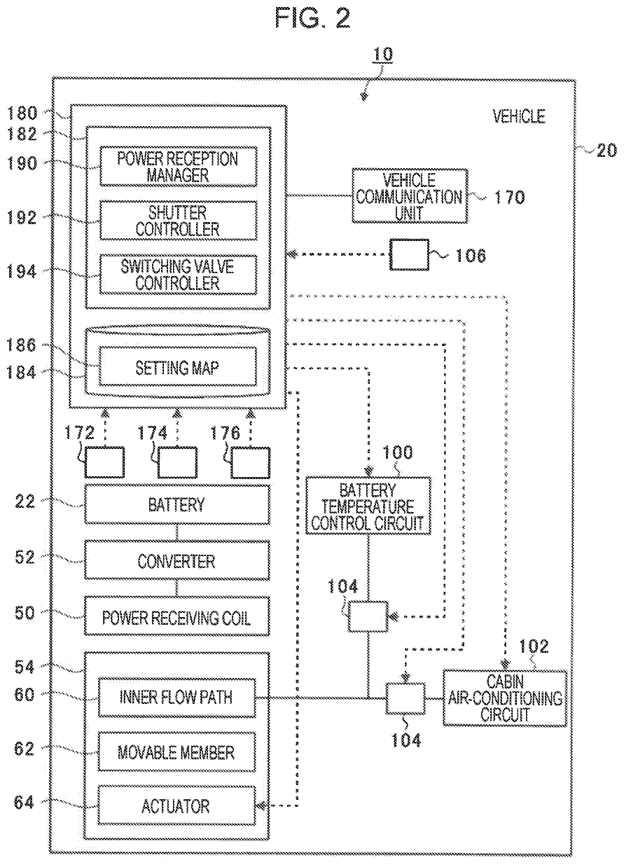

FIG. 2 is a block diagram illustrating a configuration of the vehicle 20 to which the contactless charger 10 is applied. As illustrated in FIG. 2, the shutter 54 includes an inner flow path 60, a movable member 62, and an actuator 64.

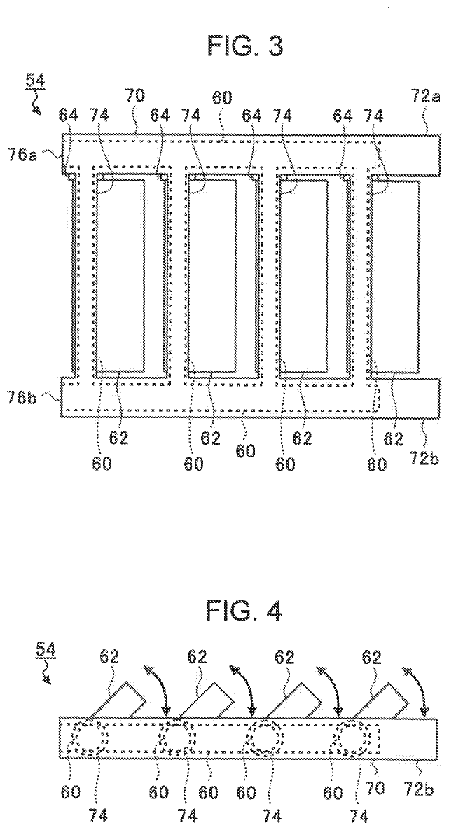

FIG. 3 is a plan view of the shutter 54. FIG. 4 is a side view of the shutter 54. As illustrated in FIGS. 3 and 4, the shutter 54 includes a frame 70 forming the inner flow path 60. The frame 70 includes a rod-shaped first support post 72a, a rod-shaped second support post 72b, and cylindrical shafts 74, and it is constituted in the form of a ladder.

In more detail, the first support post 72a and the second support post 72b are arranged parallel to each other. One of two ends of each shaft 74 is coupled to the first support post 72a, and the other end is coupled to the second support post 72b. The shafts 74 extend perpendicularly to the first support post 72a and the second support post 72b. The shafts 74 are arranged parallel to each other at intervals in the lengthwise direction of the first support post 72a and the second support post 72b.

The inner flow path 60 is formed inside the first support post 72a, the second support post 72b, and the shafts 74 to extend in the lengthwise direction thereof. At one of ends of each shaft 74, the inner flow path 60 of the shaft 74 is fluid-communicated with the inner flow path 60 of the first support post 72a. At the other end of the shaft 74, the inner flow path 60 of the shaft 74 is fluid-communicated with the inner flow path 60 of the second support post 72b.

A first fluid communication port 76a at which the inner flow path 60 is opened to the outside of the first support post 72a is formed at one end of the first support post 72a. The other end of the first support post 72a on an opposite side to the first fluid communication port 76a is closed. A second fluid communication port 76b at which the inner flow path 60 is opened to the outside of the second support post 72b is formed at one end of the second support post 72b. The other end of the second support post 72b on an opposite side to the second fluid communication port 76b is closed.

A heat medium flows through the inner flow path 60. The heat medium is, for example, water or the like but may be any medium that is contributable to heat exchange. The heat medium flows into the inner flow path 60 of the first support post 72a through the first fluid communication port 76a, for example. The heat medium having flowed into the inner flow path 60 of the first support post 72a flows through the inner flow path 60 in each of the shafts 74 and move to the inner flow path 60 of the second support post 72b. The heat medium in the inner flow path 60 of the second support post 72b flows out from the second fluid communication port 76b. Instead, the heat medium may flow into the inner flow path 60 through the second fluid communication port 76b and may flow out from the first fluid communication port 76a.

The movable member 62 is disposed for each of the shafts 74. As denoted by a double-headed arrow in FIG. 4, the movable member 62 is coupled to the shaft 74 rotatably about an axis of the shaft 74. For example, the movable member 62 includes a cylindrical portion that is concentric with the shaft 74 and that is positioned on an outer circumferential side of the shaft 74. The cylindrical portion is rotatable relative to the shaft 74 about the axis of the shaft 74.

The movable member 62 extends from the shaft 74 in the radial direction of the shaft 74. For example, the movable member 62 includes a plate that is coupled to the above-mentioned cylindrical portion and that extends from the cylindrical portion in the radial direction of the shaft 74. Furthermore, the movable member 62 spreads in the lengthwise direction of the shaft 74. The movable member 62 is configured to be able to close a space formed between the shaft 74 to which the movable member 62 is coupled and the shaft 74 adjacent to the former shaft 74.

The frame 70 is positioned below the power receiving coil 50 and is arranged substantially parallel to the power receiving coil 50. As described above, the movable member 62 is rotatable relative to the shaft 74. Thus, the movable member 62 can be opened and closed relative to the frame 70 in a fashion of changing a projected area of the movable member 62 when it is projected to (namely, with respect to) the power receiving coil 50.

The actuator 64 rotates the movable member 62 relative to the shaft 74. In other words, the actuator 64 opens and closes the movable member 62 relative to the frame 70.

The movable member 62 is made of a material that generates a current due to electromagnetic induction when the movable member 62 receives a time-varying magnetic flux, and that generates heat with the generated current. Thus, the movable member 62 is made of a material, such as a metal containing iron, with which induction heating is properly caused. A thickness of the movable member 62 is about several millimeters. The movable member 62 may have any thickness at which the induction heating is properly caused.

When, as described above, the movable member 62 is disposed to face the power supply coil 30 and the electromagnetic wave delivered from the power supply coil 30 reaches the movable member 62, an eddy current generates in the movable member 62 due to the time-varying magnetic flux of the electromagnetic wave, and the movable member 62 generates heat. In other words, the movable member 62 generates heat due to the electromagnetic induction induced with the power supply coil 30. The movable member 62 can transfer the generated heat to the heat medium flowing in the inner flow path 60 through the shaft 74.

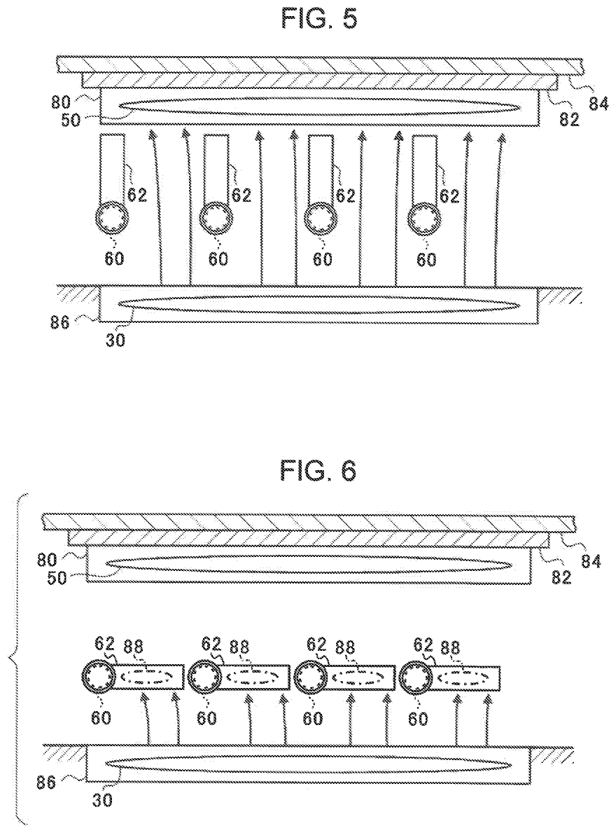

FIGS. 5 to 7 are explanatory views illustrating actions of the shutter 54. FIGS. 5 to 7 represent a case where the power receiving coil 50 is positioned to face the power supply coil 30. Each arrow in FIGS. 5 to 7 indicates, as a visible image, the magnetic flux generating around the power supply coil 30 upon the power being supplied to the power supply coil 30.

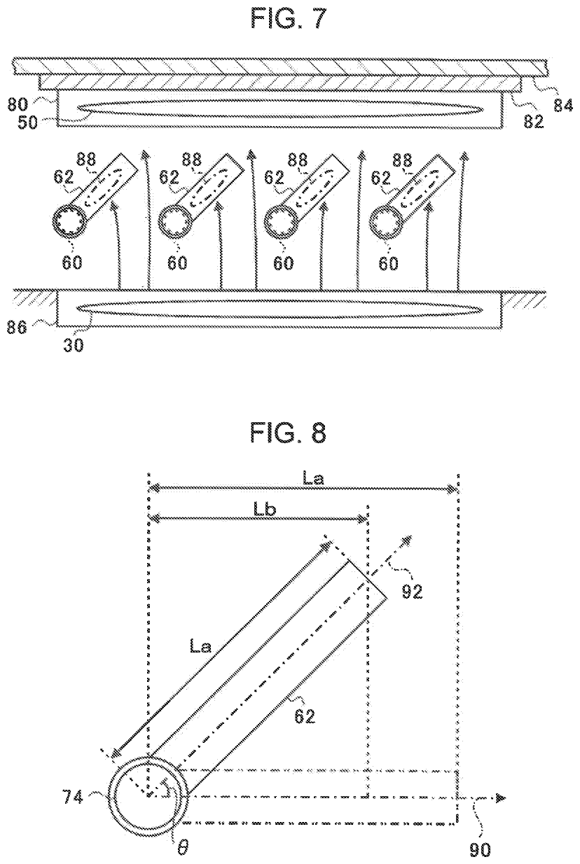

FIG. 5 represents a case where the movable member 62 is “fully opened” relative to the frame 70. The “fully opened” state corresponds to a case where an angle of the movable member 62 relative to the lengthwise direction of the first support post 72a or the second support post 72b is 90°. FIG. 6 represents a case where the movable member 62 is “fully closed” relative to the frame 70. The “fully closed” state corresponds to a case where the angle of the movable member 62 relative to the lengthwise direction of the first support post 72a or the second support post 72b is 0°. FIG. 7 represents one example of a case where the movable member 62 takes any angle between the “fully opened” state and the “fully closed” state relative to the frame 70. In the example illustrated in FIG. 7, the angle of the movable member 62 relative to the lengthwise direction of the first support post 72a or the second support post 72b is 45°. For convenience of explanation, the case of FIG. 7 is also hereinafter called a case where the movable member 62 is inclined.

As illustrated in FIGS. 5 to 7, the power receiving coil 50 is housed in a power receiving coil case 80. The power receiving coil case 80 is mounted to a vehicle body 84 with a shield 82 interposed therebetween. The power supply coil 30 is housed in a power supply coil case 86 and is installed in the ground.

As illustrated in FIGS. 5 and 7, when the movable member 62 is opened relative to the frame 70, the movable member 62 is rotated to be open toward the power receiving coil 50 relative to the frame 70. Instead, the movable member 62 may be rotated to be open toward an opposite side to the power receiving coil 50 relative to the frame 70.

As illustrated in FIG. 5, when the movable member 62 is fully opened, the projected area of the movable member 62 with respect to the power receiving coil 50 is minimum. In this case, the magnetic flux generated from the power supply coil 30 passes through empty spaces in the frame 70 and reaches the power receiving coil 50 without being intercepted by the movable members 62. In this case, the power receiving coil 50 can receive large part of the power of the electromagnetic wave delivered from the power supply coil 30.

Furthermore, when the movable member 62 is fully opened, the magnetic flux hardly hits against the movable member 62, and therefore the movable member 62 hardly generates heat. In this case, heat is not supplied to the heat medium in the inner flow path 60 from the movable member 62.

As illustrated in FIG. 6, when the movable member 62 is fully closed, the projected area of the movable member 62 with respect to the power receiving coil 50 is maximum. In this case, most of the magnetic flux generated from the power supply coil 30 is intercepted by the movable member 62, and the magnetic flux hardly reaches the power receiving coil 50. In this case, the power receiving coil 50 does not substantially receive the power of the electromagnetic wave delivered from the power supply coil 30.

Furthermore, when the movable member 62 is fully closed, the magnetic flux generated from the power supply coil 30 hits against the movable member 62, and hence an eddy current 88 generates in the movable member 62 as denoted by a one-dot-chain line in FIG. 6. With the eddy current 88 generating in the movable member 62, the movable member 62 generates heat, and the generated heat is transferred to the heat medium in the inner flow path 60. When the movable member 62 is fully closed, the movable member 62 generates a lot of heat because a large amount of magnetic flux hits against the movable member 62. In this case, a lot of heat is transferred to the inner flow path 60, and a temperature of the heat medium is apt to rise.

As illustrated in FIG. 7, when the movable member 62 is inclined, part of the magnetic flux generated from the power supply coil 30 passes through the empty spaces between the movable members 62 and the frame 70 and reaches the power receiving coil 50. The power receiving coil 50 can receive the power corresponding to an amount of the magnetic flux having reached the power receiving coil 50 through the above-mentioned empty spaces. The empty spaces increase as the angle of the movable member 62 increases. Accordingly, as the angle of the movable member 62 increases, the power received by the power receiving coil 50 increases.

Furthermore, when the movable member 62 is inclined, some of the magnetic flux generated from the power supply coil 30 hits against the movable member 62. Accordingly, the eddy current 88 generates in the movable member 62 corresponding to an amount of the magnetic flux hitting against the movable member 62. In the movable member 62, heat is generated in amount corresponding to the magnitude of the eddy current 88. The generated heat is transferred to the heat medium in the inner flow path 60, and the temperature of the heat medium rises. Thus, as the angle of the movable member 62 reduces, the amount of heat generated in the movable member 62 increases, and the temperature of the heat medium is more apt to rise.

As described above, in the contactless charger 10, the power received by the power receiving coil 50 can be restricted or regulated in accordance with the angle of the movable member 62, namely with the projected area of the movable member 62 with respect to the power receiving coil 50. Moreover, in the contactless charger 10, the temperature of the heat medium can be raised with part of the power of the electromagnetic wave delivered from the power supply coil 30, the part being not transferred to the power receiving coil 50 because of the presence of the movable member 62. The heat of the heat medium is utilized, as described later, to control a temperature of the battery 22 and to perform air conditioning in the cabin of the vehicle 20.

FIG. 8 illustrates an example of a method of determining the angle of the movable member 62. A one-dot-chain line 90 in FIG. 8 denotes the lengthwise direction of the first support post 72a or the second support post 72b. A one-dot-chain line 92 in FIG. 8 denotes the extension direction of the movable member 62. An angle θ in FIG. 8 denotes the angle of the movable member 62 relative to the frame 70. For convenience of understanding, in FIG. 8, the movable member 62 when the angle of the movable member 62 is 0° is illustrated with a two-dot-chain line.

Here, as illustrated in FIG. 8, a length of the movable member 62 in the extension direction is assumed to be La. A length of the movable member 62 in the lengthwise direction of the first support post 72a or the second support post 72b when the angle of the movable member 62 is θ is assumed to be Lb. The length Lb corresponds to cosine when the angle of the movable member 62 is θ (Lb=La cos θ).

When the angle of the movable member 62 is 0°, the projected area of the movable member 62 with respect to the power receiving coil 50 corresponds to the length La. When the angle of the movable member 62 is θ, the projected area of the movable member 62 with respect to the power receiving coil 50 corresponds to the length Lb. In other words, when the projected area in the state of the angle of the movable member 62 being 0° is assumed to be a reference, the projected area in the state of the angle of the movable member 62 being θ corresponds to a value (Lb/La) resulting from dividing the length Lb by the length La.

As described above, the received power relative to the supplied power from the power supply coil 30 depends on the projected area of the movable member 62 with respect to the power receiving coil 50. Thus, the value (Lb/La) resulting from dividing the length Lb by the length La corresponds to a value (received power/supplied power) resulting from dividing the received power by the supplied power. As seen from the above discussion, the angle θ of the movable member 62 can be derived from the following formula (1).

θ=arccos(received power/supplied power) (1)

Returning to FIG. 2, the vehicle 20 includes a battery temperature control circuit 100, a cabin air-conditioning circuit 102, switching valves 104, and a cabin air-conditioning switch 106. The battery temperature control circuit 100 is a thermal circuit in which the heat medium for controlling the temperature of the battery 22 circulates. Hereinafter, the temperature of the battery 22 is called the “battery temperature” in some cases. The cabin air-conditioning circuit 102 is a thermal circuit in which the heat medium contributing to the air conditioning in the cabin of the vehicle 20 circulates.

The inner flow path 60 of the shutter 54 can be coupled to the battery temperature control circuit 100 through the one or multiple switching valves 104. The inner flow path 60 of the shutter 54 can also be coupled to the cabin air-conditioning circuit 102 through the one or multiple switching valves 104. The switching valves 104 can turn on or off coupling between the battery temperature control circuit 100 and the inner flow path 60 and can turn on or off coupling between the cabin air-conditioning circuit 102 and the inner flow path 60.

The cabin air-conditioning switch 106 accepts an input operation for switching on or off the air conditioning in the cabin. When the cabin air-conditioning switch 106 is turned on by the input operation of an occupant in the vehicle 20, the air conditioning in the cabin is performed. When the cabin air-conditioning switch 106 is turned off, the air conditioning in the cabin is stopped.

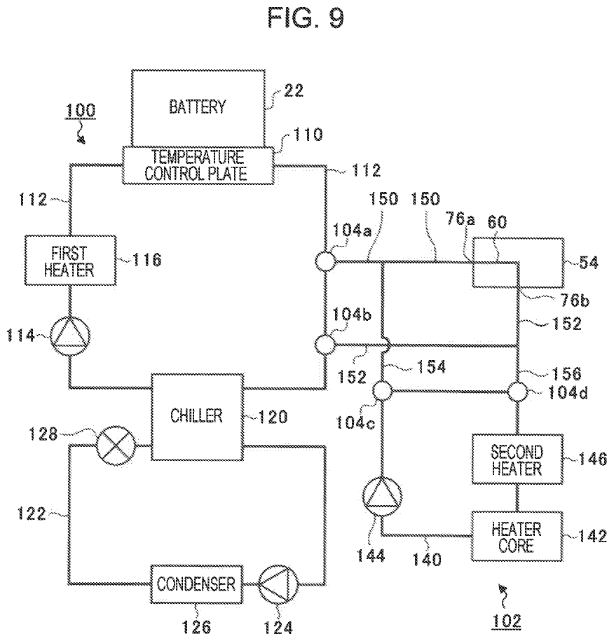

FIG. 9 is a schematic view illustrating coupling relationships among the inner flow path 60, the battery temperature control circuit 100, and the cabin air-conditioning circuit 102. As illustrated in FIG. 9, the battery temperature control circuit 100 includes a temperature control plate 110, a battery temperature control pipe 112, a first pump 114, a first heater 116, a chiller 120, a battery temperature control sub-pipe 122, a compressor 124, a condenser 126, and an expansion valve 128.

The temperature control plate 110 is disposed under the battery 22 and is held in contact with the battery 22. The battery temperature control pipe 112 is routed to extend from the temperature control plate 110 and return to the temperature control plate 110 after passing the chiller 120, the first pump 114, and the first heater 116 in the order mentioned. A heat medium flows through the battery temperature control pipe 112. The heat medium is, for example, water or the like but may be any medium that is contributable to heat exchange.

The temperature control plate 110 performs the heat exchange between the heat medium supplied through the battery temperature control pipe 112 and the battery 22 and controls the temperature of the battery 22. The first pump 114 circulates the heat medium in the battery temperature control pipe 112. The first heater 116 heats the heat medium in the battery temperature control pipe 112 while consuming the power of the battery 22.

Not only the battery temperature control pipe 112, but also the battery temperature control sub-pipe 122 is coupled to the chiller 120. The battery temperature control sub-pipe 122 is routed to extend from the chiller 120 and return to the chiller 120 after passing the compressor 124, the condenser 126, and the expansion valve 128 in the order mentioned. A heat medium flows through the battery temperature control sub-pipe 122 separately from the heat medium flowing through the battery temperature control pipe 112. The heat medium in the battery temperature control sub-pipe 122 is, for example, water or the like but may be any medium that is contributable to heat exchange.

The compressor 124 compresses the heat medium in gas phase sent into the compressor 124 from the chiller 120 side through the battery temperature control sub-pipe 122 and sends out the compressed heat medium to the condenser 126. The condenser 126 performs heat exchange between air outside the vehicle 20 and the heat medium compressed by the compressor 124 and releases heat of the heat medium to the outside of the vehicle 20. The heat medium in the condenser 126 is cooled in a high-pressure state and hence causes a phase transition from gas phase to liquid phase.

The expansion valve 128 sprays the heat medium sent into the expansion valve 128 from the condenser 126 side toward the chiller 120 side. The sprayed heat medium causes a phase transition to liquid phase due to an abrupt drop of pressure. A temperature of the heat medium drops because of the above-mentioned vaporization. The chiller 120 performs heat exchange between the heat medium in the battery temperature control sub-pipe 122 and the heat medium in the battery temperature control pipe 112 and cools the heat medium in the battery temperature control pipe 112.

Here, for example, when the battery temperature is between an upper limit threshold and a lower limit threshold of the temperature control, the first pump 114 and the compressor 124 are stopped, and the first heater 116 does not heat the heat medium in the battery temperature control pipe 112. In this case, the temperature control of the battery 22 by the temperature control plate 110 is stopped.

For example, when the battery temperature exceeds the upper limit threshold in the temperature control, the compressor 124 is driven, and hence the heat medium in the battery temperature control pipe 112 is cooled by the chiller 120. The first pump 114 is driven while the heating by the first heater 116 is not performed. Therefore, the heat medium in the battery temperature control pipe 112, cooled by the chiller 120, is supplied to the temperature control plate 110. As a result, a rise of the battery temperature is suppressed.

For example, when the battery temperature exceeds the lower limit threshold in the temperature control, the compressor 124 is held stopped, and the cooling of the heat medium in the battery temperature control pipe 112 by the chiller 120 is not performed. The heat medium in the battery temperature control pipe 112 is heated by the first heater 116, and the first pump 114 is driven to supply the heat medium heated by the first heater 116 to the temperature control plate 110. As a result, a drop of the battery temperature is suppressed.

As illustrated in FIG. 9, the cabin air-conditioning circuit 102 includes a cabin air-conditioning pipe 140, a heater core 142, a second pump 144, and a second heater 146.

The cabin air-conditioning pipe 140 is routed to extend from the heater core 142 and return to the heater core 142 after passing the second pump 144 and the second heater 146 in the order mentioned. A heat medium flows through the cabin air-conditioning pipe 140. The heat medium is, for example, water or the like but may be any medium that is contributable to heat exchange.

Air is sent to the heater core 142 from, for example, a blower. The heater core 142 performs heat exchange between the heat medium supplied through the cabin air-conditioning pipe 140 and the air. The air after the heat exchange is sent to the cabin. The second pump 144 circulates the heat medium in the cabin air-conditioning pipe 140. The second heater 146 heats the heat medium in the cabin air-conditioning pipe 140 while consuming the power of the battery 22.

Here, for example, when the cabin air-conditioning switch 106 is turned off, the second pump 144 is stopped, and the second heater 146 does not heat the heat medium in the cabin air-conditioning pipe 140. The blower for sending the air to the heater core 142 is also stopped. In this case, the air conditioning in the cabin is stopped.

For example, when the cabin air-conditioning switch 106 is turned on, the second heater 146 heats the heat medium in the cabin air-conditioning pipe 140, and the second pump 144 is driven. Therefore, the heat medium heated by the second heater 146 is supplied to the heater core 142. Moreover, the blower is driven, and the air warmed by the heat exchange with the heat medium in the heater core 142 is sent to the cabin.

The coupling between the inner flow path 60 of the shutter 54 and the battery temperature control circuit 100 and the coupling between the inner flow path 60 of the shutter 54 and the cabin air-conditioning circuit 102 will be described below.

The vehicle 20 includes, as the switching valves 104, a first switching valve 104a, a second switching valve 104b, a third switching valve 104c, and a fourth switching valve 104d. The first switching valve 104a, the second switching valve 104b, the third switching valve 104c, and the fourth switching valve 104d are each, for example, a three-way valve. The vehicle 20 further includes a first bypass pipe 150, a second bypass pipe 152, a third bypass pipe 154, and a fourth bypass pipe 156.

The first switching valve 104a is disposed in the battery temperature control pipe 112 between the temperature control plate 110 and the chiller 120. The second switching valve 104b is disposed in the battery temperature control pipe 112 between the first switching valve 104a and the chiller 120.

The first bypass pipe 150 is coupled to the first fluid communication port 76a of the inner flow path 60. The first bypass pipe 150 extends from the first fluid communication port 76a and is coupled to the first switching valve 104a.

A first port of the first switching valve 104a is coupled to the battery temperature control pipe 112 on a side fluid-communicating with the temperature control plate 110. A second port of the first switching valve 104a is coupled to the battery temperature control pipe 112 on a side fluid-communicating with the chiller 120. A third port of the first switching valve 104a is coupled to the first bypass pipe 150. The first switching valve 104a can switch the state in which a flow between the first port and the second port is allowed while a flow toward the third port is shut off, and the state in which a flow between the first port and the third port is allowed while a flow toward the second port is shut off.

The second bypass pipe 152 is coupled to the second fluid communication port 76b of the inner flow path 60. The second bypass pipe 152 extends from the second fluid communication port 76b and is coupled to the second switching valve 104b.

A first port of the second switching valve 104b is coupled to the battery temperature control pipe 112 on a side fluid-communicating with the temperature control plate 110. A second port of the second switching valve 104b is coupled to the battery temperature control pipe 112 on a side fluid-communicating with the chiller 120. A third port of the second switching valve 104b is coupled to the second bypass pipe 152. The second switching valve 104b can switch the state in which a flow between the first port and the second port is allowed while a flow toward the third port is shut off, and the state in which a flow between the second port and the third port is allowed while a flow toward the first port is shut off.

The third switching valve 104c is disposed in the cabin air-conditioning pipe 140 between the second pump 144 and the second heater 146. The fourth switching valve 104d is disposed in the cabin air-conditioning pipe 140 between the third switching valve 104c and the second heater 146.

The third bypass pipe 154 is coupled to an intermediate point of the first bypass pipe 150. The third bypass pipe 154 is branched from the first bypass pipe 150 to extend therefrom and is coupled to the third switching valve 104c.

A first port of the third switching valve 104c is coupled to the cabin air-conditioning pipe 140 on a side fluid-communicating with the second pump 144. A second port of the third switching valve 104c is coupled to the cabin air-conditioning pipe 140 on a side fluid-communicating with the second heater 146. A third port of the third switching valve 104c is coupled to the third bypass pipe 154. The third switching valve 104c can switch the state in which a flow between the first port and the second port is allowed while a flow toward the third port is shut off, and the state in which a flow between the first port and the third port is allowed while a flow toward the second port is shut off.

The fourth bypass pipe 156 is coupled to an intermediate point of the second bypass pipe 152. The fourth bypass pipe 156 is branched from the second bypass pipe 152 to extend therefrom and is coupled to the fourth switching valve 104d.

A first port of the fourth switching valve 104d is coupled to the cabin air-conditioning pipe 140 on a side fluid-communicating with the second pump 144. A second port of the fourth switching valve 104d is coupled to the cabin air-conditioning pipe 140 on a side fluid-communicating with the second heater 146. A third port of the fourth switching valve 104d is coupled to the fourth bypass pipe 156. The fourth switching valve 104d can switch the state in which a flow between the first port and the second port is allowed while a flow toward the third port is shut off, and the state in which a flow between the second port and the third port is allowed while a flow toward the first port is shut off.

In the vehicle 20 to which the contactless charger 10 is applied, heat medium flow paths can be switched by controlling respective states of the first switching valve 104a, the second switching valve 104b, the third switching valve 104c, and the fourth switching valve 104d.

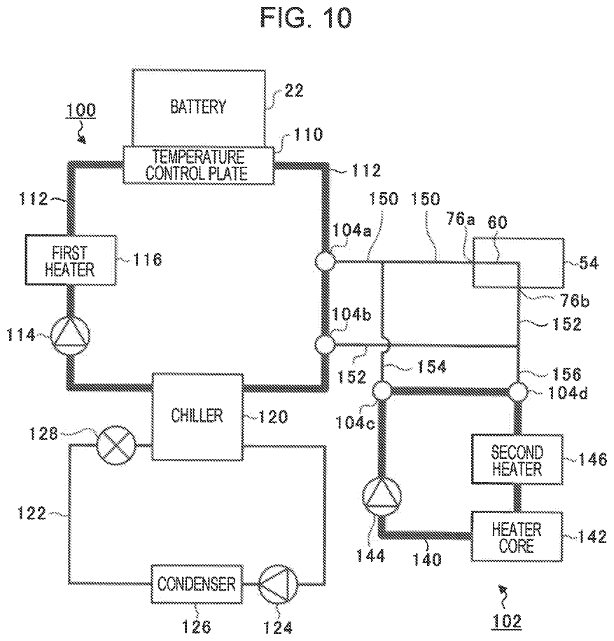

FIGS. 10 to 14 illustrate examples of the heat medium flow paths. In FIGS. 10 to 14, the flow path through which the heat medium circulates is denoted by thick lines.

In the example of FIG. 10, the first switching valve 104a is in the state allowing a flow between a point of the battery temperature control pipe 112 on the side fluid-communicating with the temperature control plate 110 and a point of the battery temperature control pipe 112 on the side fluid-communicating with the chiller 120 among the pipes coupled to the first switching valve 104a. In a different aspect, the first switching valve 104a is in the state shutting off a flow toward the first bypass pipe 150 among the pipes coupled to the first switching valve 104a. The second switching valve 104b is in the state allowing a flow between a point of the battery temperature control pipe 112 on the side fluid-communicating with the temperature control plate 110 and a point of the battery temperature control pipe 112 on the side fluid-communicating with the chiller 120 among the pipes coupled to the second switching valve 104b. In a different aspect, the second switching valve 104b is in the state shutting off a flow toward the second bypass pipe 152 among the pipes coupled to the second switching valve 104b.

Thus, in the example of FIG. 10, the inner flow path 60 of the shutter 54 is decoupled from the battery temperature control circuit 100 by the first switching valve 104a and the second switching valve 104b. In this example, therefore, the heat medium in the battery temperature control pipe 112 circulates through the flow path along the battery temperature control pipe 112 without passing the shutter 54.

Furthermore, in the example of FIG. 10, the third switching valve 104c is in the state allowing a flow between a point of the cabin air-conditioning pipe 140 on the side fluid-communicating with the second pump 144 and a point of the cabin air-conditioning pipe 140 on the side fluid-communicating with the second heater 146 among the pipes coupled to the third switching valve 104c. In a different aspect, the third switching valve 104c is in the state shutting off a flow toward the third bypass pipe 154 among the pipes coupled to the third switching valve 104c. The fourth switching valve 104d is in the state allowing a flow between a point of the cabin air-conditioning pipe 140 on the side fluid-communicating with the second pump 144 and a point of the cabin air-conditioning pipe 140 on the side fluid-communicating with the second heater 146 among the pipes coupled to the fourth switching valve 104d. In a different aspect, the fourth switching valve 104d is in the state shutting off a flow toward the fourth bypass pipe 156 among the pipes coupled to the fourth switching valve 104d.

Thus, in the example of FIG. 10, the inner flow path 60 of the shutter 54 is decoupled from the cabin air-conditioning circuit 102 by the third switching valve 104c and the fourth switching valve 104d. In this example, therefore, the heat medium in the cabin air-conditioning pipe 140 circulates through the flow path along the cabin air-conditioning pipe 140 without passing the shutter 54.

The example of FIG. 10 has been described in connection with an example in which the heat medium circulates in each of the battery temperature control circuit 100 and the cabin air-conditioning circuit 102. However, the heat medium may be circulated in either one of the battery temperature control circuit 100 and the cabin air-conditioning circuit 102, and the circulation of the heat medium may be stopped in the other. As an alternative, the circulation of the heat medium may be stopped in each of those two circuits.

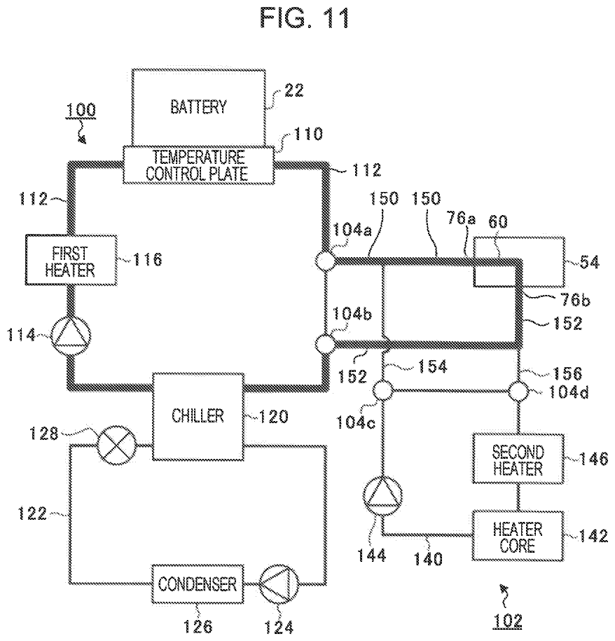

In the example of FIG. 11, the first switching valve 104a is in the state allowing a flow between the point of the battery temperature control pipe 112 on the side fluid-communicating with the temperature control plate 110 and the first bypass pipe 150 among the pipes coupled to the first switching valve 104a. In a different aspect, the first switching valve 104a is in the state shutting off a flow toward the point of the battery temperature control pipe 112 on the side fluid-communicating with the chiller 120 among the pipes coupled to the first switching valve 104a. The second switching valve 104b is in the state allowing a flow between the point of the battery temperature control pipe 112 on the side fluid-communicating with the chiller 120 and the second bypass pipe 152 among the pipes coupled to the second switching valve 104b. In a different aspect, the second switching valve 104b is in the state shutting off a flow toward the point of the battery temperature control pipe 112 on the side fluid-communicating with the temperature control plate 110 among the pipes coupled to the second switching valve 104b.

Furthermore, the third switching valve 104c is in the state allowing the flow between the point of the cabin air-conditioning pipe 140 on the side fluid-communicating with the second pump 144 and the point of the cabin air-conditioning pipe 140 on the side fluid-communicating with the second heater 146 among the pipes coupled to the third switching valve 104c. In a different aspect, the third switching valve 104c is in the state shutting off the flow toward the third bypass pipe 154 among the pipes coupled to the third switching valve 104c. The fourth switching valve 104d is in the state allowing the flow between the point of the cabin air-conditioning pipe 140 on the side fluid-communicating with the second pump 144 and the point of the cabin air-conditioning pipe 140 on the side fluid-communicating with the second heater 146 among the pipes coupled to the fourth switching valve 104d. In a different aspect, the fourth switching valve 104d is in the state shutting off the flow toward the fourth bypass pipe 156 among the pipes coupled to the fourth switching valve 104d.

Thus, in the example of FIG. 11, the inner flow path 60 of the shutter 54 is coupled to the battery temperature control circuit 100 by the first switching valve 104a and the second switching valve 104b. In this example, the heat medium delivered from the second fluid communication port 76b of the inner flow path 60 is sent to the battery temperature control pipe 112 through the second bypass pipe 152 and the second switching valve 104b. The heat medium sent to the battery temperature control pipe 112 moves through the chiller 120, the first pump 114, the first heater 116, the temperature control plate 110, the first switching valve 104a, and the first bypass pipe 150 in the order mentioned and returns to the inner flow path 60 through the first fluid communication port 76a. Accordingly, the heat transferred from the movable member 62 to the heat medium in the inner flow path 60 is transferred to the temperature control plate 110 with the circulation of the heat medium and contributes to the temperature control of the battery 22 executed by the temperature control plate 110.

Moreover, in the example of FIG. 11, the cabin air-conditioning circuit 102 is decoupled from the inner flow path 60 by the third switching valve 104c and the fourth switching valve 104d. Additionally, in the example of FIG. 11, the second pump 144 is stopped, and the heat medium in the cabin air-conditioning pipe 140 is not circulated.

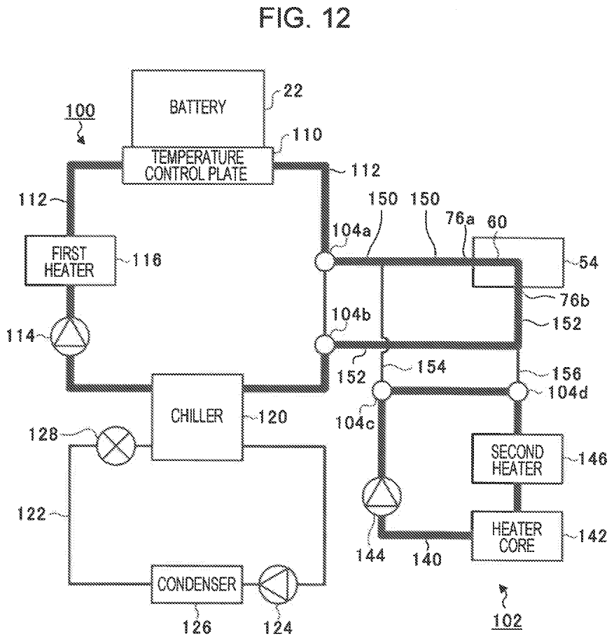

In the example of FIG. 12, the states of the switching valves 104 constituting the first switching valve 104a to the fourth switching valve 104d are the same as those in FIG. 11. Thus, in the example of FIG. 12, the cabin air-conditioning circuit 102 is decoupled from the inner flow path 60 by the third switching valve 104c and the fourth switching valve 104d. Stated another way, in the example of FIG. 12, the inner flow path 60 is coupled to the battery temperature control circuit 100 whereas the heat medium in the cabin air-conditioning pipe 140 is circulated merely in the cabin air-conditioning circuit 102.

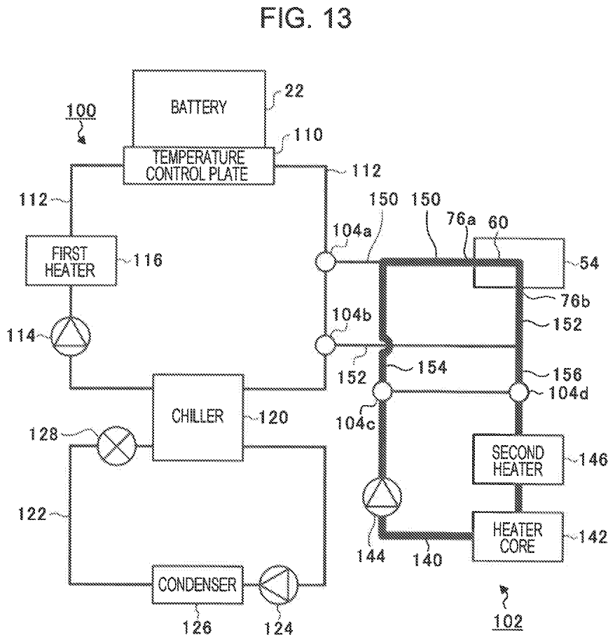

In the example of FIG. 13, the third switching valve 104c is in the state allowing a flow between the point of the cabin air-conditioning pipe 140 on the side fluid-communicating with the second pump 144 and the third bypass pipe 154 among the pipes coupled to the third switching valve 104c. In a different aspect, the third switching valve 104c is in the state shutting off a flow toward the point of the cabin air-conditioning pipe 140 on the side fluid-communicating with the second heater 146 among the pipes coupled to the third switching valve 104c. The fourth switching valve 104d is in the state allowing a flow between the point of the cabin air-conditioning pipe 140 on the side fluid-communicating with the second heater 146 and the fourth bypass pipe 156 among the pipes coupled to the fourth switching valve 104d. In a different aspect, the fourth switching valve 104d is in the state shutting off a flow toward the point of the cabin air-conditioning pipe 140 on the side fluid-communicating with the second pump 144 among the pipes coupled to the fourth switching valve 104d.

Furthermore, the first switching valve 104a is in the state allowing the flow between the point of the battery temperature control pipe 112 on the side fluid-communicating with the temperature control plate 110 and the point of the battery temperature control pipe 112 on the side fluid-communicating with the chiller 120 among the pipes coupled to the first switching valve 104a. In a different aspect, the first switching valve 104a is in the state shutting off the flow toward the first bypass pipe 150 among the pipes coupled to the first switching valve 104a. The second switching valve 104b is in the state allowing the flow between the point of the battery temperature control pipe 112 on the side fluid-communicating with the temperature control plate 110 and the point of the battery temperature control pipe 112 on the side fluid-communicating with the chiller 120 among the pipes coupled to the second switching valve 104b. In a different aspect, the second switching valve 104b is in the state shutting off the flow toward the second bypass pipe 152 among the pipes coupled to the second switching valve 104b.

Thus, in the example of FIG. 13, the inner flow path 60 of the shutter 54 is coupled to the cabin air-conditioning circuit 102 by the third switching valve 104c and the fourth switching valve 104d. In this example, the heat medium delivered from the second fluid communication port 76b of the inner flow path 60 is sent to the cabin air-conditioning pipe 140 through the second bypass pipe 152, the fourth bypass pipe 156, and the fourth switching valve 104d. The heat medium sent to the cabin air-conditioning pipe 140 moves through the second heater 146, the heater core 142, the second pump 144, the third switching valve 104c, the third bypass pipe 154, and the first bypass pipe 150 in the order mentioned and returns to the inner flow path 60 through the first fluid communication port 76a. Accordingly, the heat transferred from the movable member 62 to the heat medium in the inner flow path 60 is transferred to the heater core 142 with the circulation of the heat medium and contributes to the air conditioning in the cabin.

Moreover, in the example of FIG. 13, the battery temperature control circuit 100 is decoupled from the inner flow path 60 by the first switching valve 104a and the second switching valve 104b. Additionally, in the example of FIG. 13, the first pump 114 is stopped, and the heat medium in the battery temperature control pipe 112 is not circulated.

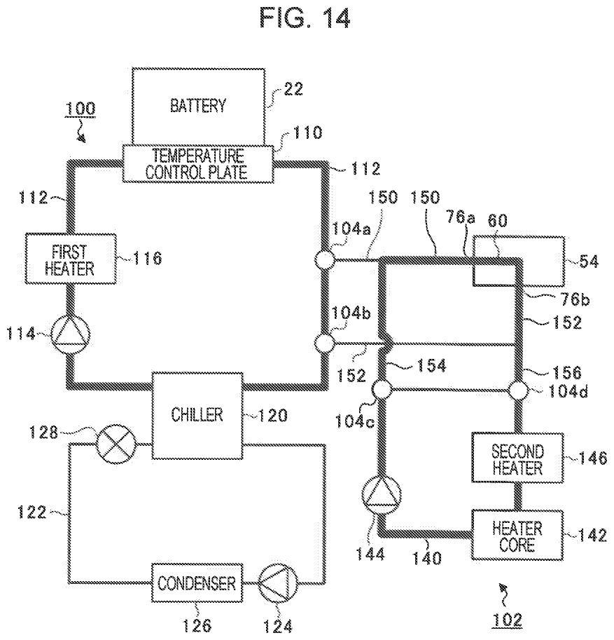

In the example of FIG. 14, the states of the switching valves 104 constituting the first switching valve 104a to the fourth switching valve 104d are the same as those in FIG. 13. Thus, in the example of FIG. 14, the battery temperature control circuit 100 is decoupled from the inner flow path 60 by the first switching valve 104a and the second switching valve 104b. Stated another way, in the example of FIG. 14, the inner flow path 60 is coupled to the cabin air-conditioning circuit 102 whereas the heat medium in the battery temperature control pipe 112 is circulated merely in the battery temperature control circuit 100.

Returning to FIG. 2, the vehicle 20 includes a vehicle communication unit 170, a temperature sensor 172, a voltage sensor 174, a current sensor 176, and a control device 180.

The vehicle communication unit 170 can communicate with any communication device outside the vehicle 20. In an example, the vehicle communication unit 170 can communicate with the equipment communication unit 34 in the power supply equipment 12.

The temperature sensor 172 detects the battery temperature. The voltage sensor 174 detects a voltage at an input/output terminal of the battery 22. The current sensor 176 detects a current flowing through the input/output terminal of the battery 22.

The control device 180 includes ore or multiple processors 182 and one or multiple memories 184 coupled to the one or multiple processors 182. The one or multiple memories 184 include ROM in which programs and so on are stored, and RAM serving as a work area.

A setting map 186 is previously stored in the one or multiple memories 184. Information regarding an opening degree of the movable member 62 and information regarding the coupling of the inner flow path 60 are set in the setting map 186. Linking between the information regarding the coupling of the inner flow path 60 and the states of the individual switching valves 104 may also be set in the setting map 186. Details of the setting map 186 will be described later.

The one or multiple processors 182 cooperate with the programs stored in the one or multiple memories 184 and control individual components of the vehicle 20. The one or multiple processors further serve as a power reception manager 190, a shutter controller 192, and a switching valve controller 194 by executing the programs.

The power reception manager 190 manages power reception through the power receiving coil 50. In an example, the power reception manager 190 can communicate with the power supply equipment 12 via the vehicle communication unit 170 and can obtain information regarding the supplied power from the power supply coil 30. The power reception manager 190 further determines whether the power receiving coil 50 is at a position where the power receiving coil 50 can contactlessly receive the power from the power supply coil 30.

The power reception manager 190 may further derive a SOC (State of Charge) of the battery 22 as appropriate. The SOC is expressed as a percentage of a present charging capacity relative to a full charging capacity and represents a charging rate of the battery 22. In addition, the power reception manager 190 may obtain the battery temperature detected by the temperature sensor 172 as appropriate.

Moreover, the power reception manager 190 may turn on a cabin air-conditioning flag when the cabin air-conditioning switch 106 is turned on and may turn off the cabin air-conditioning flag when the cabin air-conditioning switch 106 is turned off. The cabin air-conditioning flag indicates whether there is a request for the air conditioning in the cabin. The cabin air-conditioning flag is stored in, for example, the one or multiple memories 184 and is maintained until the state of the cabin air-conditioning flag is changed.

When the power receiving coil 50 is at the position where the power receiving coil 50 can contactlessly receive the power from the power supply coil 30, the shutter controller 192 controls the opening degree of the movable member 62 based on the SOC of the battery 22, the battery temperature, and the presence of the request for the air conditioning in the cabin. The wording “control of the opening degree of the movable member 62” indicates control of the angle of the movable member 62.

In an example, the shutter controller 192 derives the angle of the movable member 62 by referring to the setting map 186. Alternatively, the shutter controller 192 may derive, based on the battery temperature, the received power that is receivable at that time, and may derive, based on the received power and the supplied power, the angle of the movable member 62 from the above-described formula (1). The shutter controller 192 drives the actuator 64 for the shutter 54 such that the angle of the movable member 62 is held at the derived angle.

When the power receiving coil 50 is at the position where the power receiving coil 50 can contactlessly receive the power from the power supply coil 30, the switching valve controller 194 controls switching of the switching valves 104 based on the SOC of the battery 22, the battery temperature, and the presence of the request for the air conditioning in the cabin. The wording “switching of the switching valves 104” indicates that the respective states of the first switching valve 104a to the fourth switching valve 104d are switched, more specifically indicates that combinations of the port allowing the flow therethrough and the port shutting off the flow therethrough are switched.

In an example, for each of the switching valves 104, an actuator for switching the switching valve 104 is disposed. The switching valve controller 194 refers to the setting map 186 and determines the state of each switching valve 104. The switching valve controller 194 drives the actuator such that the state of each switching valve 104 is held in the determined state.

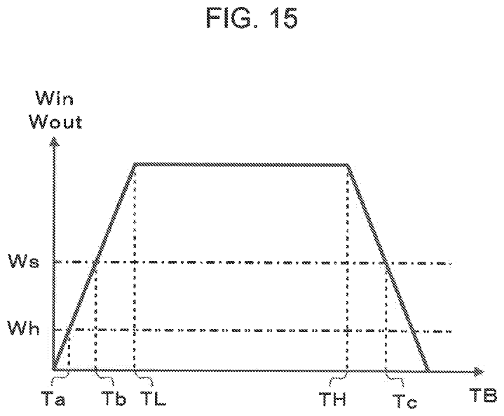

FIG. 15 illustrates power input/output characteristics of the battery 22. TB in FIG. 15 denotes the battery temperature. Win in FIG. 15 denotes allowable maximum input power, namely maximum power capable of being input to the battery 22. Wout in FIG. 15 denotes allowable maximum output power, namely maximum power capable of being output from the battery 22. A characteristic of the allowable maximum input power Win relative to the battery temperature TB and a characteristic of the allowable maximum output power Wout relative to the battery temperature TB change almost in the same way.

As illustrated in FIG. 15, the battery temperature has, for each type of the battery 22, a proper range where the power can be appropriately input and output. As the temperature of the battery 22 drops below a lower limit temperature TL of the proper temperature range, the allowable maximum input power Win and the allowable maximum output power Wout reduce. Similarly, as the temperature of the battery 22 rises above an upper limit temperature TH of the proper temperature range, the allowable maximum input power Win and the allowable maximum output power Wout reduce.

Here, it is assumed, for example, that supplied power Ws is output from the power supply coil 30. A temperature Tb represents a temperature that is lower than the lower limit temperature TL and that corresponds to an intersect between the supplied power Ws and the allowable maximum input power Win. A temperature Tc represents a temperature that is higher than the upper limit temperature TH and that corresponds to an intersect between the supplied power Ws and the allowable maximum input power Win.

As illustrated in FIG. 15, if the battery temperature TB is higher than or equal to the temperature Tb even though it is lower than the lower limit temperature TL, the supplied power Ws can be all received and input to the battery 22. However, if the battery temperature TB is lower than the temperature Tb, the allowable maximum input power Win is lower than the supplied power Ws. Accordingly, even when the supplied power Ws is received, part of the supplied power Ws cannot be input to the battery 22.

As in the above-described low temperature case, if the battery temperature TB is lower than or equal to the temperature Tc even though it is higher than the upper limit temperature TH, the supplied power Ws can be all received and input to the battery 22. However, if the battery temperature TB is higher than the temperature Tc, the allowable maximum input power Win is lower than the supplied power Ws. Accordingly, even when the supplied power Ws is received, part of the supplied power Ws cannot be input to the battery 22.

Taking into consideration the above point, in the contactless charger 10, when the allowable maximum input power Win is lower than the supplied power Ws, the opening degree of the movable member 62 is adjusted to restrict the received power such that the received power is held almost equal to the allowable maximum input power Win. As a result, the received power can be all input to the battery 22.

Furthermore, in the contactless charger 10, part of the supplied power Ws, the part being intercepted by the movable member 62, is converted to heat in the movable member 62, and the generated heat is transferred to the heat medium in the inner flow path 60. In the contactless charger 10, the heat transferred to the heat medium in the inner flow path 60 can be further transferred to the temperature control plate 110 in the battery temperature control circuit 100 and can contribute to the temperature control of the battery 22. Moreover, in the contactless charger 10, the heat transferred to the heat medium in the inner flow path 60 can also be transferred to the heater core 142 in the cabin air-conditioning circuit 102 and can contribute to the air conditioning in the cabin as well.

As described above, in the contactless charger 10, even when the battery temperature is outside the proper range, the supplied power Ws can be utilized without a loss.

Wh in FIG. 15 denotes heater lowest power, namely lowest power that is to be consumed by the first heater 116 or the second heater 146 to heat the heat medium. A temperature Ta represents a temperature that is lower than the lower limit temperature TL and that corresponds to an intersect between the heater lowest power Wh and the allowable maximum output power Wout.

As illustrated in FIG. 15, when the battery temperature TB is higher than or equal to the temperature Ta, the power consumed by the first heater 116 or the second heater 146 can be output from the battery 22. However, when the battery temperature TB is lower than the temperature Ta, the power consumed by the first heater 116 or the second heater 146 cannot be output from the battery 22 because the allowable maximum output power Wout is lower than the heater lowest power Wh.

Taking into consideration the above point, in the contactless charger 10, when the power receiving coil 50 is at the position where the power receiving coil 50 can contactlessly receive the power from the power supply coil 30 under the condition of the battery temperature TB being lower than the temperature Ta, the movable member 62 is controlled such that at least part of the supplied power is intercepted by the movable member 62. The power intercepted by the movable member 62 is converted to heat in the movable member 62, and the generated heat is transferred to the heat medium in the inner flow path 60. In the contactless charger 10, the heat transferred to the heat medium in the inner flow path 60 can be further transferred to the temperature control plate 110 in the battery temperature control circuit 100 and can contribute to the temperature control of the battery 22. Moreover, in the contactless charger 10, the heat transferred to the heat medium in the inner flow path 60 can also be transferred to the heater core 142 in the cabin air-conditioning circuit 102 and can contribute to the air conditioning in the cabin as well.

As described above, in the contactless charger 10, even when the battery temperature TB is reduced to a low level at which the power consumed by the first heater 116 cannot be output from the battery 22, the battery temperature can be raised with the heat generated in the movable member 62. Moreover, in the contactless charger 10, even when the battery temperature TB is reduced to a low level at which the power consumed by the second heater 146 cannot be output from the battery 22, the air conditioning in the cabin can be performed.

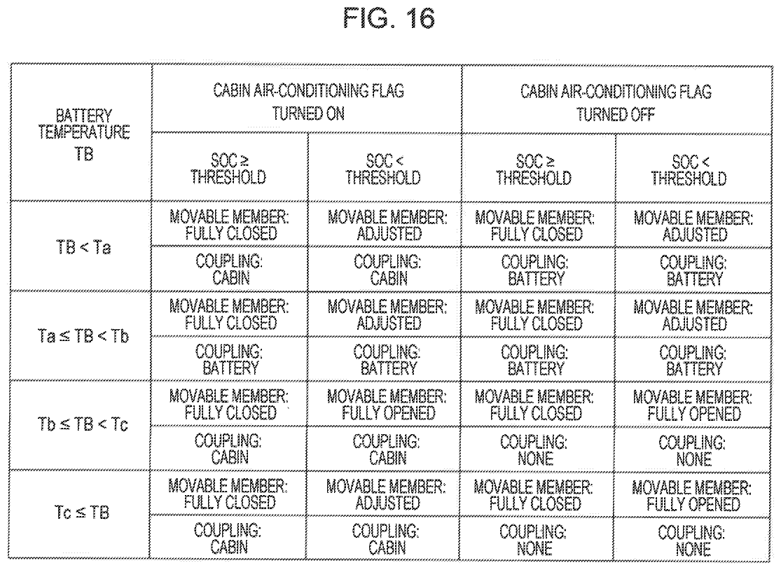

FIG. 16 illustrates an example of the setting map 186. As illustrated in FIG. 16, in the setting map 186, the opening degree of the movable member 62 and a coupling mode of the inner flow path 60 are set for each of combinations of the cabin air-conditioning flag, the SOC, and the battery temperature.

In FIG. 16, “MOVABLE MEMBER: FULLY OPENED, FULLY CLOSED, or ADJUSTED” indicates the opening degree of the movable member. “ADJUSTED” indicates that the movable member is adjusted to any opening degree between “FULLY OPENED” and “FULLY CLOSED”. In the case of “ADJUSTED”, the shutter controller 192 derives the allowable maximum input power from the present battery temperature and sets the derived allowable maximum input power as the received power that is receivable at that time. The shutter controller 192 derives the angle of the movable member from that received power and the supplied power.

“COUPLING: BATTERY, CABIN, or NONE” indicates the coupling mode of the inner flow path 60. “COUPLING: BATTERY” indicates that the switching valves 104 are set to establish a state in which the inner flow path 60 and the battery temperature control circuit 100 are coupled to each other. Thus, “COUPLING: BATTERY” corresponds to the coupling mode illustrated in FIG. 11 or 12.

“COUPLING: CABIN” indicates that the switching valves 104 are set to establish a state in which the inner flow path 60 and the cabin air-conditioning circuit 102 are coupled to each other. Thus, “COUPLING: CABIN” corresponds to the coupling mode illustrated in FIG. 13 or 14.

“COUPLING: NONE” indicates that the switching valves 104 are set to establish a state in which the inner flow path is decoupled from both the battery temperature control circuit and the cabin air-conditioning circuit. Thus, “COUPLING: NONE” corresponds to the coupling mode illustrated in FIG. 10.

“THRESHOLD” in “SOC THRESHOLD” corresponds to a reference for use in determining whether the charging of the battery 22 is necessary. In other words, “SOC THRESHOLD” indicates that the charging of the battery 22 is not necessary. “SOC<THRESHOLD” indicates that the charging of the battery 22 is necessary. Ta, Tb and Tc in FIG. 16 are the same as Ta, Tb, and Tc in FIG. 15, respectively.

As illustrated in FIG. 16, in the case of the cabin air-conditioning flag being turned on, SOC THRESHOLD, and TB<Ta, the movable member 62 is set to the “FULLY CLOSED”, and the inner flow path 60 is coupled to the cabin air-conditioning circuit 102. The reason why the movable member 62 is fully closed is that the charging of the battery 22 is not necessary. The reason why the inner flow path 60 is coupled to the cabin air-conditioning circuit 102 is that the air conditioning in the cabin is requested and the air conditioning in the cabin is given with higher priority than the temperature control of the battery 22. Consequently, most of the supplied power is converted to heat in the movable member 62, and the converted heat contributes to the air conditioning in the cabin.

In the case of the cabin air-conditioning flag being turned on, SOC≥THRESHOLD, and Ta≤TB<Tb, the movable member 62 is set to the “FULLY CLOSED”, and the inner flow path 60 is coupled to the battery temperature control circuit 100. The reason why the movable member 62 is fully closed is that the charging of the battery 22 is not necessary. Furthermore, in this case, because the battery temperature TB is higher than the temperature Ta, the power consumed by the second heater 146 is output from the battery 22, and the air conditioning in the cabin is performed with heat generated from the second heater 146.

In addition, because the battery temperature TB is lower than the temperature Tb, there is a possibility that the battery 22 cannot output the power covering the power consumed by the first heater 116 as well. Accordingly, the inner flow path 60 is coupled to the battery temperature control circuit 100. Thus, most of the supplied power is converted to heat in the movable member 62, and the converted heat contributes to the temperature control of the battery 22. Here, it is considered that heating with the heat from the second heater 146 causes a smaller energy loss than heating with the heat from the movable member 62. For that reason, the second heater 146 is used with higher priority given to the air conditioning in the cabin than to the temperature control of the battery 22.

In the case of the cabin air-conditioning flag being turned on, SOC THRESHOLD, and Tb TB<Tc, the movable member 62 is set to the “FULLY CLOSED”, and the inner flow path 60 is coupled to the cabin air-conditioning circuit 102. In this case, most of the supplied power is intercepted by the movable member 62 and is converted to heat. The converted heat contributes to the air conditioning in the cabin.

In the case of the cabin air-conditioning flag being turned on, SOC THRESHOLD, and Tc TB, the movable member 62 is set to the “FULLY CLOSED”, and the inner flow path 60 is coupled to the cabin air-conditioning circuit 102. In this case, most of the supplied power is intercepted by the movable member 62 and is converted to heat. The converted heat contributes to the air conditioning in the cabin.

In the case of the cabin air-conditioning flag being turned on, SOC<THRESHOLD, and TB<Ta, the air conditioning in the cabin is requested, and the charging is necessary. Therefore, the movable member 62 is set to the “ADJUSTED”, and the inner flow path 60 is coupled to the cabin air-conditioning circuit 102. In this case, by restricting the received power to the allowable maximum input power with the movable member 62, the battery 22 can be properly charged in spite of TB<Ta. Moreover, part of the supplied power, the part being intercepted by the movable member 62, is converted to heat, and the converted heat contributes to the air conditioning in the cabin. Accordingly, the supplied power can be utilized without a loss.

In the case of the cabin air-conditioning flag being turned on, SOC<THRESHOLD, and Ta TB<Tb, the movable member 62 is set to the “ADJUSTED”, and the inner flow path 60 is coupled to the battery temperature control circuit 100. Because of Ta TB, the power consumed by the second heater 146 is output from the battery 22, and the air conditioning in the cabin is performed with the heat from the second heater 146. Moreover, the charging is necessary under the condition of TB<Tb. Thus, the battery 22 can be properly charged by restricting the received power to the allowable maximum input power with the movable member 62. In addition, part of the supplied power, the part being intercepted by the movable member 62, is converted to heat, and the converted heat contributes to the temperature control of the battery 22. Accordingly, the supplied power can be utilized without a loss.

In the case of the cabin air-conditioning flag being turned on, SOC<THRESHOLD, and Tb TB<Tc, the movable member 62 is set to the “FULLY OPENED”, and the inner flow path 60 is coupled to the cabin air-conditioning circuit 102. Because of Tb TB<Tc, the power consumed by the second heater 146 is output from the battery 22, and the air conditioning in the cabin is performed with the heat from the second heater 146. Furthermore, because Tb TB<Tc is held and the allowable maximum input power is higher than the supplied power, the movable member 62 is fully opened. It is estimated that heat hardly generates in the movable member 62 because the movable member 62 is fully opened. However, the inner flow path 60 is coupled to the cabin air-conditioning circuit 102 for the sake of reducing a loss in consideration of that the cabin air-conditioning flag is turned on.

In the case of the cabin air-conditioning flag being turned on, SOC<THRESHOLD, and Tc TB, the movable member 62 is set to the “ADJUSTED”, and the inner flow path 60 is coupled to the cabin air-conditioning circuit 102. The charging is necessary under the condition of Tc TB. Thus, the battery 22 can be properly charged by restricting the received power to the allowable maximum input power with the movable member 62. In addition, part of the supplied power, the part being intercepted by the movable member 62, is converted to heat, and the converted heat contributes to the air conditioning in the cabin. Accordingly, the supplied power can be utilized without a loss.

In the case of the cabin air-conditioning flag being turned off, SOC THRESHOLD, and TB<Ta, the movable member 62 is set to the “FULLY CLOSED”, and the inner flow path 60 is coupled to the battery temperature control circuit 100. Because the charging is not necessary, the movable member 62 is fully closed. Furthermore, because of TB<Ta, most of the supplied power is intercepted by the movable member 62 and is converted to heat. The converted heat contributes to the temperature control of the battery 22.

In the case of the cabin air-conditioning flag being turned off, SOC THRESHOLD, and Ta TB<Tb, the movable member 62 is set to the “FULLY CLOSED”, and the inner flow path 60 is coupled to the battery temperature control circuit 100. Because the charging is not necessary, the movable member 62 is fully closed. Furthermore, because of TB<Tb, most of the supplied power is intercepted by the movable member 62 and is converted to heat. The converted heat contributes to the temperature control of the battery 22.

In the case of the cabin air-conditioning flag being turned off, SOC THRESHOLD, and Tb TB<Tc, the movable member 62 is set to the “FULLY CLOSED”, and the coupling of the inner flow path 60 is set to “NONE”. Because the charging is not necessary, the movable member 62 is fully closed. Furthermore, because Tb TB<Tc is held and the cabin air-conditioning flag is turned off, the heat from the movable member 62 is not necessary to assist the temperature control of the battery 22 and the air conditioning in the cabin. Therefore, the inner flow path 60 is decoupled from both the battery temperature control circuit 100 and the cabin air-conditioning circuit 102.

In the case of the cabin air-conditioning flag being turned off, SOC THRESHOLD, and Tc TB, the movable member 62 is set to the “FULLY CLOSED”, and the coupling of the inner flow path 60 is set to “NONE”. Because the charging is not necessary, the movable member 62 is fully closed. Furthermore, because Tc TB is held and the cabin air-conditioning flag is turned off, the heat from the movable member 62 is not necessary to assist the temperature control of the battery 22 and the air conditioning in the cabin. Therefore, the inner flow path 60 is decoupled from both the battery temperature control circuit 100 and the cabin air-conditioning circuit 102.

In the case of the cabin air-conditioning flag being turned off, SOC<THRESHOLD, and TB<Ta, the movable member 62 is set to the “ADJUSTED”, and the inner flow path 60 is coupled to the battery temperature control circuit 100. In this case, by restricting the received power to the allowable maximum input power with the movable member 62, the battery 22 can be properly charged in spite of TB<Ta. Moreover, part of the supplied power, the part being intercepted by the movable member 62, is converted to heat, and the converted heat contributes to the temperature control of the battery 22. Accordingly, the supplied power can be utilized without a loss.

In the case of the cabin air-conditioning flag being turned off, SOC<THRESHOLD, and Ta TB<Tb, the movable member 62 is set to the “ADJUSTED”, and the inner flow path 60 is coupled to the battery temperature control circuit 100. In this case, by restricting the received power to the allowable maximum input power with the movable member 62, the battery 22 can be properly charged in spite of TB<Tb. Moreover, part of the supplied power, the part being intercepted by the movable member 62, is converted to heat, and the converted heat contributes to the temperature control of the battery 22. Accordingly, the supplied power can be utilized without a loss.

In the case of the cabin air-conditioning flag being turned off, SOC<THRESHOLD, and Tb TB<Tc, the movable member 62 is set to the “FULLY OPENED”, and the coupling of the inner flow path 60 is set to “NONE”. Because the charging is necessary, the movable member 62 is fully opened. Furthermore, because Tb TB<Tc is held and the cabin air-conditioning flag is turned off, the heat from the movable member 62 is not necessary to assist the temperature control of the battery 22 and the air conditioning in the cabin. Therefore, the inner flow path 60 is decoupled from both the battery temperature control circuit 100 and the cabin air-conditioning circuit 102.

In the case of the cabin air-conditioning flag being turned off, SOC<THRESHOLD, and Tc TB, the movable member 62 is set to the “FULLY OPENED”, and the coupling of the inner flow path 60 is set to “NONE”. Because the charging is necessary, the movable member 62 is fully opened. Furthermore, because Tc TB is held and the cabin air-conditioning flag is turned off, the heat from the movable member 62 is not necessary to assist the temperature control of the battery 22 and the air conditioning in the cabin. Therefore, the inner flow path 60 is decoupled from both the battery temperature control circuit 100 and the cabin air-conditioning circuit 102.

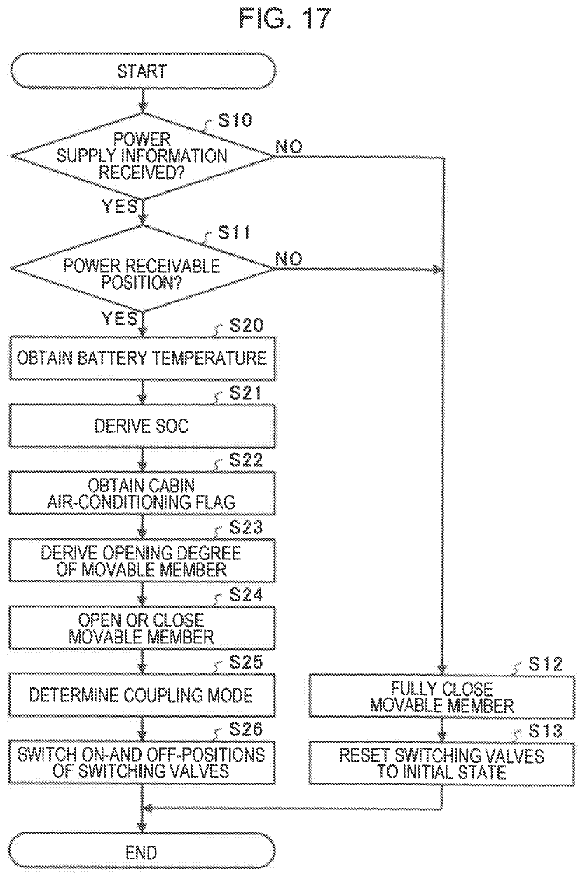

FIG. 17 is a flowchart illustrating an operation flow of the control device 180. The power reception manager 190 in the control device 180 executes a series of processing steps illustrated in FIG. 17 at predetermined interrupt timing that comes at a predetermined interval.

Upon reaching the predetermined interrupt timing, the power reception manager 190 first determines whether, from any power supply equipment 12, power supply information representing information of the supplied power from the power supply coil 30 in the power supply equipment 12 of interest is received (S10). The power supply information may include, for example, information indicating that the power can be supplied, and may include, when the power can be supplied, information indicating how much the supplied power is.

If the power supply information is received (YES in S10), it is estimated that the power supply equipment 12 exists near a vehicle of interest. Therefore, the power reception manager 190 determines whether the vehicle is at the position where the vehicle can receive the power from the power supply equipment 12. For example, when the power received by the power receiving coil 50 is greater than or equal to a threshold, the power reception manager 190 may determine that the vehicle is at the power receivable position. A practical method of determining whether the vehicle is at the power receivable position is not limited to the above-mentioned example. In another example, the power reception manager 190 may execute the determination by utilizing the GPS, for example.

If the power supply information is not received (NO in S10), it is estimated that the power supply equipment 12 does not exist near the vehicle. Therefore, the power reception manager 190 advances to processing of step S12. If it is determined that the vehicle is not at the power receivable position (NO in S11), the power reception manager 190 also advances to the processing of step S12 because the vehicle is estimated to be not in the state capable of properly receiving the power.

In step S12, the power reception manager 190 fully closes the movable member 62 (S12). This enables the power receiving coil 50 to be protected by the shutter 54 when the power receiving coil 50 does not receive the power.

After step S12, the power reception manager 190 resets the switching valves 104 to an initial state (S13) and finishes the series of the processing steps. The initial state of the switching valves 104 is assumed to be the state in which the inner flow path 60 is decoupled from both the battery temperature control circuit 100 and the cabin air-conditioning circuit 102.

If it is determined that the vehicle is at the power receivable position (YES in S11), the power reception manager 190 executes processing of step S20 and subsequent steps because the power receiving coil 50 is estimated to be at the position where it can contactlessly receive the power from the power supply coil 30.

In step S20, the power reception manager 190 obtains the present battery temperature detected by the temperature sensor 172 (S20). The power reception manager 190 derives the present SOC based on the present voltage of the battery 22 detected by the voltage sensor 174 (S21). The power reception manager 190 reads and obtains the present cabin air-conditioning flag from the memory 184 (S22).

The shutter controller 192 refers to the setting map 186 and derives the opening degree of the movable member 62 from the present battery temperature, the present SOC, and the present cabin air-conditioning flag (S23). When a result of referring to the setting map 186 indicates that the movable member 62 is to be “ADJUSTED”, the shutter controller 192 derives the allowable maximum input power from the present battery temperature. The shutter controller 192 sets the allowable maximum input power as the received power and derives the angle of the movable member 62 from that received power and the supplied power obtained from the power supply information. The derived angle corresponds to the opening degree.

Then, the shutter controller 192 opens or closes the movable member 62 by the actuator 64 such that the derived opening degree is held (S24).

The switching valve controller 194 refers to the setting map 186 and determines the coupling mode of the inner flow path 60 from the present battery temperature, the present SOC, and the present cabin air-conditioning flag (S25).

Then, the switching valve controller 194 switches the switching valves 104 such that the coupling mode of the inner flow path 60 is established as per the determined coupling mode (S26). The series of the processing steps is thereby finished.

Suppose, for example, that the inner flow path 60 is determined to be coupled to the battery temperature control circuit 100. In this example, the switching valve controller 194 turns the first switching valve 104a into the state allowing the flow between the point of the battery temperature control pipe 112 on the side fluid-communicating with the temperature control plate 110 and the first bypass pipe 150. The switching valve controller 194 turns the second switching valve 104b into the state allowing the flow between the point of the battery temperature control pipe 112 on the side fluid-communicating with the chiller 120 and the second bypass pipe 152. The switching valve controller 194 turns the third switching valve 104c into the state allowing the flow between the point of the cabin air-conditioning circuit 102 on the side fluid-communicating with the second pump 144 and the third bypass pipe 154. The switching valve controller 194 turns the fourth switching valve 104d into the state allowing the flow between the point of the cabin air-conditioning circuit 102 on the side fluid-communicating with the second heater 146 and the fourth bypass pipe 156.

As described above, the contactless charger 10 according to this embodiment includes the movable member 62. The movable member 62 can be opened and closed in a fashion of changing the projected area of the movable member 62 with respect to the power receiving coil 50, can generate heat due to electromagnetic induction induced with the power supply coil 30, and can transfer the generated heat to the heat medium flowing through the inner flow path 60. The contactless charger 10 according to this embodiment further includes the switching valves 104. The switching valves 104 can turn on or off the coupling between the battery temperature control circuit 100 and the inner flow path 60 and can turn on or off the coupling between the cabin air-conditioning circuit 102 and the inner flow path 60.

In the contactless charger 10 according to this embodiment, therefore, even in the state in which the allowable maximum input power is smaller than the supplied power, the received power can be restricted to the allowable maximum input power and the battery 22 can be properly charged by adjusting the opening degree of the movable member 62.

In the contactless charger 10 according to this embodiment, part of the supplied power Ws, the part being intercepted by the movable member 62, is converted to heat in the movable member 62, and the generated heat is transferred to the inner flow path 60. In the contactless charger 10 according to this embodiment, when the battery temperature control circuit 100 and the inner flow path 60 are coupled to each other through the switching valves 104, the heat transferred to the inner flow path 60 can move to the battery temperature control circuit 100 and can contribute to the temperature control of the battery 22. Moreover, in the contactless charger 10 according to this embodiment, when the cabin air-conditioning circuit 102 and the inner flow path 60 are coupled to each other through the switching valves 104, the heat transferred to the inner flow path 60 can move to the cabin air-conditioning circuit 102 and can contribute to the air conditioning in the cabin.

Consequently, with the contactless charger 10 according to this embodiment, the supplied power can be utilized without a loss.

While the embodiment of the disclosure has been described above with reference to the accompanying drawings, the disclosure is of course not limited to the above-described embodiment. It is apparent that those skilled in the art can conceive various modifications and alterations within the scope defined in Claims. Those modifications and alterations are to be construed as falling within the technical scope of the disclosure.

The control device 180 illustrated in FIG. 2 can be implemented by circuitry including at least one semiconductor integrated circuit such as at least one processor (e.g., a central processing unit (CPU)), at least one application specific integrated circuit (ASIC), and/or at least one field programmable gate array (FPGA). At least one processor can be configured, by reading instructions from at least one machine readable tangible medium, to perform all or a part of functions of the power reception manager 190, a shutter controller 192, and a switching valve controller 194. Such a medium may take many forms, including, but not limited to, any type of magnetic medium such as a hard disk, any type of optical medium such as a CD and a DVD, any type of semiconductor memory (i.e., semiconductor circuit) such as a volatile memory and a non-volatile memory. The volatile memory may include a DRAM and a SRAM, and the non-volatile memory may include a ROM and a NVRAM. The ASIC is an integrated circuit (IC) customized to perform, and the FPGA is an integrated circuit designed to be configured after manufacturing in order to perform, all or a part of the functions of the modules illustrated in FIG. 2.

1. A contactless charger comprising:
a power receiving coil mounted in a vehicle and configured to contactlessly receive power from a power supply coil outside the vehicle via an electromagnetic field and to supply the received power to a battery;
a shutter disposed in the vehicle to be positioned between the power receiving coil and the power supply coil when the power receiving coil is positioned to face the power supply coil; and
switching valves, wherein
the shutter comprises:
an inner flow path through which a heat medium flows; and
a movable member configured to open and close so as to change a projected area of the movable member with respect to the power receiving coil, to generate heat due to electromagnetic induction induced with the power supply coil, and to transfer the generated heat to the heat medium flowing through the inner flow path, and
the switching valves are configured to turn on or off coupling between the inner flow path and a battery temperature control circuit in which the heat medium for adjusting a temperature of the battery circulates, and to turn on or off coupling between the inner flow path and a cabin air-conditioning circuit in which the heat medium contributing to air conditioning in a cabin of the vehicle circulates.

2. The contactless charger according to claim 1, further comprising a control device, wherein
the control device comprises:
one or multiple processors; and
one or multiple memories coupled to the one or multiple processors,
the one or multiple processors are configured to execute processing, the processing comprising:
controlling an opening degree of the movable member based on a state of charge of the battery, the temperature of the battery, and presence of a request for the air conditioning in the cabin when the power receiving coil is at a position where the power receiving coil can contactlessly receive the power from the power supply coil.

3. The contactless charger according to claim 2,
wherein the one or multiple processors are configured to execute processing, the processing further comprising:
controlling switching of the switching valves based on the state of charge of the battery, the temperature of the battery, and the presence of the request for the air conditioning in the cabin when the power receiving coil is at the position where the power receiving coil can contactlessly receive the power from the power supply coil.

4. The contactless charger according to claim 1, further comprising a control device, the control device comprising:
one or multiple processors; and
one or multiple memories coupled to the one or multiple processors,
wherein the one or multiple processors are configured to execute processing, the processing comprising:
controlling switching of the switching valves based on a state of charge of the battery, the temperature of the battery, and presence of a request for the air conditioning in the cabin when the power receiving coil is at a position where the power receiving coil can contactlessly receive the power from the power supply coil.
